(19) United States
(12) Patent Application Publication
(10) Pub. No.: US 2018/0358788 A1
(43) Pub. Date: Dec. 13, 2018

(54) Reusable Electrical Panel Cover

(71) Applicant: Mark Grendahl, Apple Valley, NY (US)

(72) Inventor: Mark Grendahl, Apple Valley, NY (US)

(21) Appl. No.: 16/003,343

(22) Filed: Jun. 8, 2018

Related U.S. Application Data
(60) Provisional application No. 62/517,353, filed on Jun. 9, 2017.

(51) Int. Cl. H02B 1/28; H05K 5/02; H02B 1/52

(52) U.S. Cl. CPC H02B 1/28; H02B 1/06; H02B 1/52; H05K 5/0239

(57) ABSTRACT

This invention relates to a reusable electrical panel cover with a rectangular and planar shape, four edges, a plurality of small openings for attaching the reusable electrical panel cover to an electrical panel box, and at least one cutout for access through the reusable electrical panel cover to the electrical panel. The plurality of small openings can be circular holes, elongated holes, or other cutout openings sufficient to allow a screw or other attaching means to attach the reusable electrical panel cover to the electrical panel box. The at least one cutout for access through the reusable electrical panel cover to the electrical panel can be pre-cutout or semi-cutout to be punched out onsite.

This application claims the filing date of and relates to the provisional application by the same inventor, Ser. No. 62/517,353 filed on Jun. 9, 2017.

### BACKGROUND OF THE INVENTION

This invention relates to a temporary and reusable electrical panel cover with an optional electrical device support.

### SUMMARY OF THE INVENTION

The reusable electrical panel cover protects non-energized and energized electrical panels during the construction phases of a building project. The reusable electrical panel cover comprises a sturdy rectangular planar panel cover, the panel cover further comprising four edges, a plurality of small openings for attaching the reusable electrical panel cover to an electrical panel box, and at least one cutout for access through the reusable electrical panel cover to the electrical panel. The plurality of small openings can be circular holes, elongated holes, or other cutout openings sufficient to allow a screw or other attaching means to attach the reusable electrical panel cover to the electrical panel box. The at least one cutout for access through the reusable electrical panel cover to the electrical panel can be pre-cutout or semi-cutout to be punched out onsite.

After the installation of the electrical panel it is frequently damaged by sheetrock, dust, plaster, paint and other debris. If the permanent panel cover is immediately installed, this too may be damaged or lost during construction. The reusable electrical panel cover eliminates safety and code violations, and potentially costly repairs to the panel, wiring, and breakers. Additionally, the reusable electrical panel cover provides the optional ability to install an electrical device needed for temporary power throughout construction, thus complying with OSHA Safety Standard and other building construction, electrical, and other applicable codes.

The reusable electrical panel cover can be made from sturdy material such as steel, aluminum, or plastic. The reusable electrical panel cover may be machine tooled using stamping or laser methods or, if made of plastic, can be plastic injection moulded. Alternatively, it may be hand tooled using the materials previously listed. Another embodiment of the invention would comprise impressions applied to the main body of the cover to provide rigidity.

Other embodiments of the reusable electrical panel cover comprise a non-rectangular planar shape, with at least one edge, at least one small opening for attaching the reusable electrical panel cover to an electrical panel box, and at least one cutout for access through the reusable electrical panel cover to the electrical panel. A further embodiment comprises an electrical device pre-installed and supported in the cutout for access through the reusable electrical panel cover. The electrical device can be a non-GFIC, a GFIC, or other electrical outlet means.

### DETAILED DESCRIPTION OF DRAWING

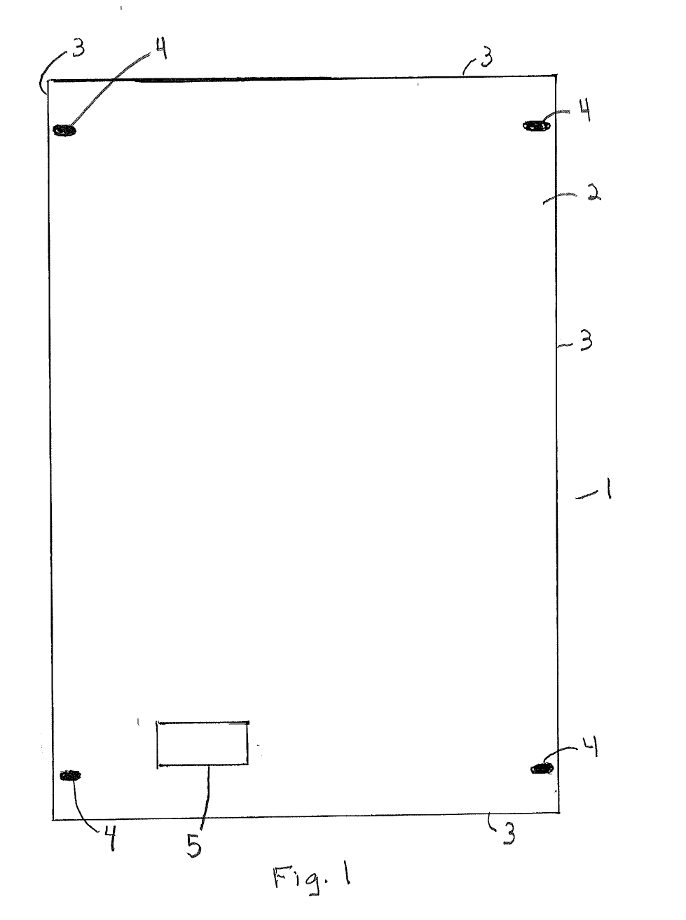

FIG. 1 shows the reusable electrical panel cover 1 comprising a sturdy rectangular planar panel cover 2, four edges 3, a plurality of small openings 4 for attaching the reusable electrical panel cover to an electrical panel box, and at least one cutout 5 for access through the reusable electrical panel cover to the electrical panel.

I claim:

1. A reusable electrical panel cover for protecting an electrical panel box.

2. The reusable electrical panel cover of claim 1 comprising a sturdy rectangular planar panel cover, the panel cover comprising two length-edge sides and two width-edge sides, a plurality of small openings for attaching the reusable electrical panel cover to an electrical panel box, and at least one cutout in the panel cover for access through the reusable electrical panel cover to the electrical panel.

3. The reusable electrical panel cover of claim 2 wherein the electrical panel cover is made of steel, aluminum or a sturdy plastic.

4. The reusable electrical panel cover of claim 2 wherein the panel cover comprises impressions applied to the cover to provide additional rigidity strength to the panel cover.

5. The reusable electrical panel cover of claim 2 further comprising an electrical device means removably installed and supported in the cutout.

6. A reusable electrical panel cover for protecting an electrical panel box comprising a sturdy rectangular planar panel cover made of steel, aluminum or a sturdy plastic, the panel cover comprising two length-edge sides and two width-edge sides, a plurality of small openings for attaching the reusable electrical panel cover to an electrical panel box, at least one cutout in the panel cover for access through the reusable electrical panel cover to the electrical panel, impressions applied to the cover to provide additional rigidity strength to the panel cover, and an electrical device means removably installed and supported in the cutout.
